(19) United States
(12) Patent Application Publication
(10) Pub. No.: US 2003/0002119 A1
(43) Pub. Date: Jan. 2, 2003

(54) Communications module having parallel transmitting diodes

(76) Inventors: Kurt Aretz, Isselburg (DE); Herwig Stange, Berlin (DE); Jurgen Blank, Berlin (DE)

Correspondence Address: LERNER AND GREENBERG, P.A., Post Office Box 2480, Hollywood, FL, 33022-2480, US

(21) Appl. No.: 10/178,666

(22) Filed: Jun. 24, 2002

Related U.S. Application Data
(63) Continuation of application No. PCT/DE00/04669, filed on Dec. 22, 2000.

(30) Foreign Application Priority Data
Dec. 23, 1999 (DE) 199 63 605.2

(51) Int. Cl. H04B 10/04; H04B 10/06; H01S 5/026

(52) U.S. Cl. 359/181; 359/189; 372/38.02

(57) ABSTRACT

A communication module includes several parallel transmitting diodes and at least one monitor transmitting diode arranged on a common substrate. The module also includes at least one monitor device consisting of a monitor transmitting diode, a receiving device and a control device. A modulated optical signal generated by a monitor transmitting diode is detected by a receiver device, and is converted and transmitted as a monitor signal to the control device. Depending on the transmitted signal, the control device generates a first control signal for the driver device with the purpose of regulating the modulation flow of the transmitting diodes and the monitor transmitting diode. The modulation amplitude for the modulation stream for the monitor transmitting diodes is lower than the modulation amplitude of the modulation stream for the transmitting diodes. The disturbing influence of the monitor signal on the data signal of the transmitting diodes is thereby minimized.

### CROSS-REFERENCE TO RELATED APPLICATION

This application is a continuation of copending International Application No. PCT/DE 00/04669, filed Dec. 22, 2000, which designated the United States.

### BACKGROUND OF THE INVENTION

### FIELD OF THE INVENTION

The invention relates to a communications module having a plurality of parallel transmitting diodes. In particular, the invention permits the stabilization of the degree of modulation of the optical output power of a plurality of transmitting diodes configured on a common substrate.

Such communications modules are used in optical waveguide equipment. A plurality of transmitting diodes are arranged one next to the other, preferably on a common substrate, so that the plurality of transmitting diodes have essentially the same electro-optical properties. Such an arrangement is referred to as a transmitting diode array. The plurality of transmitting diodes can be embodied, for example, as laser diodes.

In order to be able to use the plurality of transmitting diodes for transmitting data, the light which is emitted by the transmitting diodes is modulated in accordance with the digital data to be transmitted. The light which is emitted can be injected into optical waveguides for transmission. The plurality of transmitting diodes can be used to feed a plurality of transmission channels.

Japanese Patent application JP-336778 discloses a device having a plurality of transmitting diodes in which a monitor device is used in order to monitor and control the transmitting power of the transmitting diodes. The monitor device includes a transmitter device that is embodied as a diode, a receiver device and a control device. The light that is emitted by the transmitter device is picked up using the receiver device, which is embodied, for example, as a photo diode. A signal that is received by the receiver device is transmitted to the control device and is evaluated there. On the basis of the evaluated signal, the control device generates control signals for controlling the transmitting power of the plurality of transmitting diodes.

Published European Patent Application EP 0 525 684 A describes a communications module of the generic type having a plurality of parallel transmitting diodes and a monitor transmitting diode. The size of the modulation amplitude for compensating for the temperature dependence of the extinction ratio is selected as a function of the temperature. This results in a higher modulation amplitude for the transmitting diodes arranged in the center (at higher temperatures) than for the monitor transmitting diode located at the edge.

Published German Patent Application DE 196 23 883 A discloses a communications module of the generic type having a plurality of parallel transmitting diodes for transmitting data and a monitor transmitting diode to which a monitor diode is assigned.

### SUMMARY OF THE INVENTION

It is accordingly an object of the invention to provide a communications module which overcomes the above-mentioned disadvantages of the prior art apparatus of this general type.

In particular, it is an object of the invention to provide a communications module of the type described at the beginning that permits the monitoring and the control of the optical output power of the transmitting diodes to be improved.

With the foregoing and other objects in view there is provided, in accordance with the invention, a communication module that includes: a plurality of parallel transmitting diodes; and at least one monitor transmitting diode configured adjacent the plurality of the parallel transmitting diodes. The monitor transmitting diode has optical properties that are at least mostly similar to those of the plurality of the parallel transmitting diodes. The communication module includes at least one driver device for generating a biasing current and a modulation current for the plurality of the parallel transmitting diodes and for generating a biasing current and a modulation current for the monitor transmitting diode. The communication module includes at least one monitor device including a receiver device, a control device, and the monitor transmitting diode. The monitor transmitting diode generates a modulated optical signal. The receiver device detects the modulated optical signal, converts the modulated optical signal into a monitor signal, and transmits the monitor signal to the control device. The control device, as a function of the monitor signal transmitted by the receiver device, provides a first control signal to the driver device for setting the modulation current for the plurality of the parallel transmitting diodes and for setting the modulation current for the monitor transmitting diode. The modulation current for the plurality of the parallel transmitting diodes has a modulation amplitude. The modulation current for the monitor transmitting diode has a modulation amplitude that is smaller than the modulation amplitude of the modulation current for the plurality of the parallel transmitting diodes.

In accordance with an added feature of the invention, the monitor transmitting diode has an operating characteristic curve with a linear range; and the modulation amplitude of the modulation current for the monitor transmitting diode is at a level causing the monitor transmitting diode to always be operated in the linear range of the operating characteristic curve.

In accordance with an additional feature of the invention, the modulation amplitude of the modulation current for the monitor transmitting diode and the modulation amplitude of the modulation current for the plurality of the parallel transmitting diodes differ by a constant factor.

In accordance with another feature of the invention, the plurality of the parallel transmitting diodes have a biasing current; and the monitor transmitting diode has a biasing current. The control device is for regulating the biasing current of the plurality of the parallel transmitting diodes and for regulating the biasing current of the monitor transmitting diode. The control device includes a further control circuit for evaluating the monitor signal and for providing at least one second control signal to the driver device. The second control signal is for setting the biasing current of the plurality of the parallel transmitting diodes and for setting the biasing current of the monitor transmitting diode.

In accordance with a further feature of the invention, the monitor transmitting diode is supplied with a pilot tone frequency that is lower than that of the plurality of the parallel transmitting diodes.

In accordance with a further added feature of the invention, there is provided, a safety device. The-monitor device includes a further monitor transmitting diode and a further receiver device. The further monitor transmitting diode generates a further modulated optical signal. The further receiver device converts the further modulated optical signal into a further monitor signal. The receiver device and the further receiver device are connected to the safety device. The safety device switches off the plurality of the parallel transmitting diodes if either the received monitor signal or the further monitor signal exceeds a threshold value signal.

In accordance with a further added feature of the invention, there is provided, an OR device having a first input and a second input. The safety device includes a comparator device having a first input, a second input, and an output. The safety device also includes a further comparator device having a first input, a second input, and an output. The monitor signal is applied to the first input of the comparator device. The further received monitor signal is applied to the first input of the further comparator device. The threshold value signal is applied to the second input of the comparator device and to the second input of the further comparator device. The output of the comparator device is connected to the first input of the OR device. The output of the further comparator device is connected to the second input of the OR device.

The object of the invention is achieved by virtue of the fact that a separate transmitting diode is used for a monitor control circuit (monitor transmitting diode). The modulation amplitude of the modulation current for the monitor transmitting diode is smaller than the modulation amplitude of the modulation current for the transmitting diodes which transmit a data signal. Here, the monitor transmitting diode is adjacent to the transmitting diodes for the transmission of data and has identical, or largely similar opto-electronic properties. The modulation amplitude for the transmitting diodes can thus be set by controlling and setting the modulation amplitude of the monitor transmitting diode for the monitor circuit.

A significant advantage that is achieved with the invention in comparison with the prior art is that, by using the smaller modulation amplitude of the modulation current for the monitor transmitting diode, an interfering influence of the monitor signal on the transmitting diodes is prevented, and as a result an interfering influence on their optical output as a result of crosstalk of the monitor signal is prevented. The monitor signal forms an interference source if the transmitting diodes and the monitor transmitting diode are arranged in spatial proximity, for example, on a common substrate.

A further advantage of the inventive solution is that the transmitting diodes can also be overmodulated, i.e. can be operated with an operating current below the threshold current, while the modulation of the current for the monitor control circuit or the monitor transmitting diode, which of course has a smaller modulation amplitude, can be carried out in the linear range.

By using separate transmitting diodes for the monitor circuit, which are not optically coupled to the communication channels of the transmitting diodes, a pilot tone signal can be generated and evaluated in the monitor circuit independently of the data signals for the transmitting diodes.

A modulation amplitude within the sense of the invention should be understood as the amplitude that is defined by the HIGH level and the LOW level of a digital data signal. It is an amplitude swing. As a laser is usually activated with a power source (the output power is proportional to the current), a current is modulated and a modulation amplitude is present on the modulation current.

A preferred refinement of the invention provides for the modulation amplitude of the modulation current for the monitor transmitting diode to be so low that the monitor transmitting diode can always be operated in the linear range of the operating characteristic curve. As a result, the influence of non-linearities and resulting errors during the monitoring and control of the optical output of the transmitting diodes is avoided.

An advantageous refinement of the invention provides for the modulation amplitude of the modulation current for the monitor transmitting diode and the modulation amplitude of the modulation current for the transmitting diodes to differ by a constant factor. As a result, the modulation amplitude for the transmitting diodes can be generated using a simple amplifier circuit from the modulation amplitude for the monitor channel. A correspondingly enlarged modulation current can then be fed to the transmitting diodes. The desired modulation amplitude is therefore monitored and controlled by the monitor circuit. The modulation amplitude that is set for the monitor circuit or the monitor transmitting diode is then fed, after multiplication by a constant factor, to the transmitting diodes which transmit the data signals.

The monitor transmitting diode is advantageously supplied with a pilot tone frequency that is lower than that of the transmitting diodes. Because of the use of a separate transmitting diode for the monitor circuit, the corresponding pilot signal is completely independent of the data signals to be transmitted. The modulation amplitude of the pilot signal is registered by the monitor device and is controlled to a stable level by the control device. The modulation amplitude for the transmitting diodes is then obtained by multiplying the modulation amplitude for the transmitting diodes by a constant factor.

An advantageous development of the invention provides for the control device to control an average output power (or the biasing current) of the transmitting diodes, and for the at least one monitor transmitting diode to include a further control circuit. The signal that is received by the receiver device is evaluated by the further control circuit and the further control circuit provides at least one second control signal to the driver device for setting the biasing current of the transmitting diodes and the monitor transmitting diode. There is thus a further control possibility of the optical output power of the transmitting diodes based on the monitor signal.

In one development of the invention:

the monitor device includes a further monitor transmitting diode and a further receiver device;

a further modulated optical signal, generated by the further monitor transmitting diode, is converted into a further monitor signal by the further receiver device; and

the receiver device and the further receiver device are connected to a safety device which switches off the transmitting diodes if the received monitor signal and/or the further received monitor signal exceed a threshold value signal.

As a result, a safety device with a redundant design is provided for monitoring the transmission power of the optical output of the transmitting diodes. Two monitor channels are formed which each include a transmitter device and a receiver device and which are used independently of one another to monitor the safety of the optical output of the transmitting diodes. The upward transgression of the predefined settable threshold value signal, i.e. a specific average optical output power in one of the monitor channels leads to the transmitting diodes switching off. Even when a monitor channel fails, for example, because of a functional fault, the optical output of the transmitting diodes for the upward transgression of the threshold value signal can be monitored and an improved protection against overmodulation of the transmitting diodes is provided.

If the transmitting diodes are embodied as laser diodes, overmodulation can lead to the emission of light waves whose intensity causes damage to other components or to people. Furthermore, overmodulation can lead to the transmitting diodes themselves being destroyed.

It is advantageously possible to provide that:

the safety device includes a comparator device and a further comparator device;

the received monitor signal is applied to an input of the comparator device and the further received monitor signal is applied to an input of the further comparator device;

the threshold value signal is applied to another input of the comparator device and to another input of the further comparator device; and

an output of the comparator device and an output of the further comparator device are connected to an input or to a further input of an OR device.

As a result, the safety monitoring of the optical output of the plurality of transmitting diodes is a redundantly implemented cost-effectively using simple circuit devices.

Other features which are considered as characteristic for the invention are set forth in the appended claims.

Although the invention is illustrated and described herein as embodied in a communications module having-parallel transmitting diodes, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic view of a communications module and of an associated wiring system; and

FIG. 2 is a graph of current characteristic curves.

### DESCRIPTION OF THE PREFERRED EMBODIMENTS

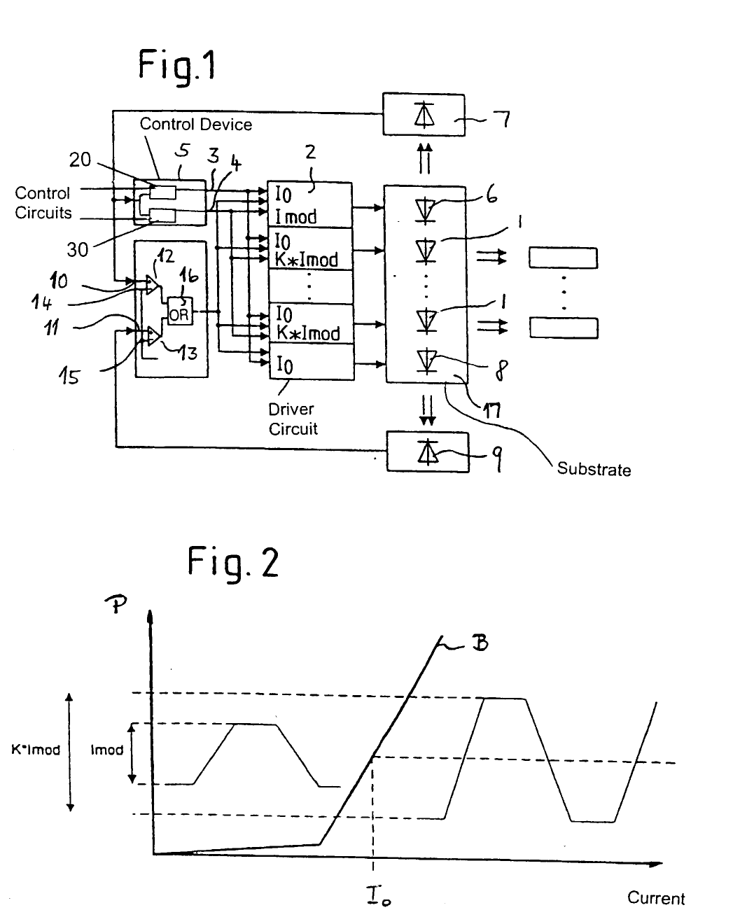

Referring now to the figures of the drawing in detail and first, particularly, to FIG. 1 thereof, there is shown a communications module for optical waveguide equipment. The communications module includes a plurality of transmitting diodes 1 that are each connected to a driver circuit 2. The driver circuit 2 is used to generate the d.c. and a.c. signals that are necessary to operate the transmitting diodes 1. These are, in particular, the biasing current for the transmitting diodes 1 onto which a modulation current which is modulated in accordance with the data to be transmitted is superimposed. The respective driver circuits 2 are connected in parallel to two outputs 3, 4 of a control device 5.

The communications module also includes two monitor channels or pilot tone channels that have a monitor transmitting diode 6 and a receiving diode 7, and a further monitor transmitting diode 8 and a further receiving diode 9. The transmitting diodes 1 and the monitor transmitting diodes 6, 8 are arranged on a common substrate 17. They are adjacent to one another and have identical or largely similar electro-optical properties. Because of the uniformity of the transmitting diodes 1 and the monitor transmitting diodes 6, 8, by controlling the optical output power of the monitor transmitting diodes 6, 8 using the monitor channels or pilot tone channels, it is also possible to control the optical output power of the transmitting diodes 1.

The transmitting diodes 1 are preferably laser diodes that emit radiation vertically with respect to the surface of the substrate.

An optical signal that is emitted by the monitor transmitting diode 6 and that is received by the receiving diode 7 is converted into a monitor signal and transmitted to the control device 5. The current (monitor signal) that is generated by the receiving diode 7 represents the output power of the monitor transmitting diode 7. For evaluating the received monitor signal, the control device 5 has a control circuit 20 and a further control circuit 30. The control circuit 20 serves to set the modulation amplitude of the monitor transmitting diode 6 and thus of the transmitting diodes 1. For this purpose, the modulation amplitude of the modulation current Imod of the monitor transmitting diode 1 is controlled. The further control circuit 30 serves (by controlling the biasing current I₀) to set the average optical output power of the monitor transmitting diode 6, and thus of the transmitting diodes 1.

A first control signal which is transmitted to the respective driver circuit 2, via a first output 3, is generated using the control circuit 20. A modulation amplitude for the modulation current of the transmitting diodes 1 is formed (a.c. actuation) in the respective driver circuits 2 using the first control signal. The modulation amplitude for the modulation current of the transmitting diodes 1 is smaller than the modulation amplitude for the modulation current of the monitor transmitting diode 6 of the monitor channel. Using the further control circuit 30, the received monitor signal is evaluated in such a way that a second control signal is generated and can be transmitted to the respective driver circuit 2 via a second output 4. The second control signal is processed in the respective driver circuit 2 in order to set an average optical output power of the transmitting diodes 1 (d.c. actuation I₀).

The received monitor signal is thus used to control the modulation amplitude of the transmitting diodes 1 and to control the average output power of the transmitting diodes 1.

The monitor signal has a frequency that is lower than the data signals of the transmitting diodes 1. It is included, for example, of a 101010 . . . pattern. In the control circuit 20, for example: the d.c. component is subtracted from the monitor signal registered by the receiving diode, the actual value is compared with a setpoint value of the modulation amplitude, and a pilot signal with a changed modulation amplitude is generated in accordance with the deviation.

According to FIG. 1, the receiving diode 7 and the further receiving diode 9 are connected to inputs 10, 11 of comparator devices 12, 13. Another input 14, 15 of the comparator devices 12, 13 is connected in each case to a comparison source (not illustrated) which generates a threshold value signal and transmits it to the other inputs 14, 15.

If the monitor signal received using the receiving diode 7 or the further receiving diode 9 exceeds the threshold value signal, at least one of the comparator devices 12, 13 transmits a signal to a logic OR device 16 which processes this signal in such a way that a switch-off signal is transmitted to the respective driver circuit 2 so that the further operation of the plurality of transmitting diodes 1, of the transmitting diode 6 and/or of the further transmitting diode 8 is interrupted.

Using the transmitting diode 6, the further transmitting diode 8, the receiving diode 7 and the further receiving diode 9, a redundant design is provided which ensures that, even when one of the monitor channels fails, it is possible to monitor the optical output of the plurality of transmitting diodes 1. Such a redundant design can, of course, also be used with known communications modules in which the transmission modulation amplitude of the optical output of the plurality of the transmitting diodes 1 is not controlled on the basis of the received monitor signal, as described above. Irrespective of this described method of controlling the transmission modulation amplitude on the basis of the evaluation of the monitor signal, the advantages of the redundant design are also obtained in conjunction with known communications modules which do not have the novel redundantly designed monitor channels. The communications module can be characterized by two monitor channels that are independent of one another and that each include a transmitter device and a receiver device. Failure of one of the two monitor channels leads to the switching off of a plurality of transmitting diodes of the communications module.

FIG. 2 shows the profile of a modulation current Imod for the transmitting diode 6. FIG. 2 also shows a modulation current k×Imod that has been amplified by the factor k for the transmitting diodes 1, and FIG. 2 shows an operating characteristic curve B of the transmitting diodes 1. During the operation of the transmitting diodes 1, they are set to a point on the operating characteristic curve B using a d.c. current (biasing current) I₀. The optical output of the plurality of transmitting diodes is then modulated with a modulation current 1 on the basis of this setting.

As shown in FIG. 2, the modulation amplitude of the amplified modulation current k×Imod is higher than the modulation amplitude of the current Imod. The modulation amplitude of the modulation current of the transmitting diodes 1 is obtained here by multiplying the constant factor k against the modulation amplitude of the modulation current Imod of the monitor transmitting diode 6. This has the advantage that the transmitting diodes 1 can also be overmodulated, i.e. can be operated with an operating current below a diode threshold current of the transmitting diodes 1. It is simultaneously assured that the monitor transmitting diode 6 is operated in a linear range.

The modulation amplitude of the transmitting diodes 1, which are used for the data transmission, is controlled by supplying the monitor transmitting diode 6 with a monitor signal (preferably low frequency). The output power of the monitor transmitting diode is registered by the receiving diode 7 and is fed to the control device 5. The amplitude or the modulation amplitude of the monitor current Imod for the monitor transmitting diode 6, and thus the modulation amplitude of the optical power of the monitor transmitting diode 6 are set to a desired value in a stable fashion by the control circuit 20. The modulation current for the transmitting diodes 1 is derived from the controlled modulation amplitude for the monitor transmitting diode 6. The modulation amplitude of the modulation current for the transmitting diodes 1 is formed by multiplying the modulation amplitude of the modulation current for the monitor transmitting diode 6 by a specific factor k which is greater than 1.

The control of the biasing current I₀ or of the average optical output power of the diodes is also carried out by the monitor channel 6, 7 using the further control circuit 30. Here, the actual value of the average optical output power in the control device 5 is compared with a setpoint value and the biasing current for the monitor transmitting diode 6 is correspondingly set. The monitor transmitting diodes 6, 8 and the transmitting diodes 1 are operated here with the same biasing current so that by controlling the biasing current of the monitor transmitting diodes 6, 8, the biasing current of the transmitting diodes is also controlled. It is to be noted that according to FIG. 1, the further monitor transmitting diode 8 is used only for the additional monitoring of the biasing current for the safety device 12, 13, 16. However, it is even possible also to apply Imod to this monitor signal and also to feed the monitor signal to the control device 5 or to a further control device.

We claim:

1. A communication module, comprising:
a plurality of parallel transmitting diodes;
at least one monitor transmitting diode configured adjacent said plurality of said parallel transmitting diodes, said monitor transmitting diode having optical properties at least mostly similar to those of said plurality of said parallel transmitting diodes;
at least one driver device for generating a biasing current and a modulation current for said plurality of said parallel transmitting diodes and for generating a biasing current and a modulation current for said monitor transmitting diode; and
at least one monitor device including a receiver device, a control device, and said monitor transmitting diode;
said monitor transmitting diode generating a modulated optical signal;
said receiver device detecting the modulated optical signal, converting the modulated optical signal into a monitor signal, and transmitting the monitor signal to said control device;
said control device, as a function of the monitor signal transmitted by said receiver device, providing a first control signal to said driver device for setting the modulation current for said plurality of said parallel transmitting diodes and for setting the modulation current for said monitor transmitting diode;
the modulation current for said plurality of said parallel transmitting diodes having-a modulation amplitude; and
the modulation current for said monitor transmitting diode having a modulation amplitude that is smaller than the modulation amplitude of the modulation current for said plurality of said parallel transmitting diodes.

2. The communications module according to claim 1, wherein:
said monitor transmitting diode has an operating characteristic curve with a linear range; and
the modulation amplitude of the modulation current for said monitor transmitting diode is at a level causing said monitor transmitting diode to always be operated in the linear range of the operating characteristic curve.

3. The communications module according to claim 1, wherein:
the modulation amplitude of the modulation current for said monitor transmitting diode and the modulation amplitude of the modulation current for said plurality of said parallel transmitting diodes differ by a constant factor.

4. The communications module according to claim 1, wherein:
said plurality of said parallel transmitting diodes have a biasing current;
said monitor transmitting diode has a biasing current;
said control device is for regulating the biasing current of said plurality of said parallel transmitting diodes and for regulating the biasing current of said monitor transmitting diode;
said control device includes a further control circuit for evaluating the monitor signal and for providing at least one second control signal to said driver device; and
the second control signal being for setting the biasing current of said plurality of said parallel transmitting diodes and for setting the biasing current of said monitor transmitting diode.

5. The communications module according to claim 1, wherein:
said monitor transmitting diode is supplied with a pilot tone frequency that is lower than that of said plurality of said parallel transmitting diodes.

6. The communications module according to claim 1, comprising:
a safety device;
said monitor device including a further monitor transmitting diode and a further receiver device;
said further monitor transmitting diode generating a further modulated optical signal;
said further receiver device converting the further modulated optical signal into a further monitor signal;
said receiver device and the further receiver device being connected to said safety device; and
said safety device switching off said plurality of said parallel transmitting diodes if a signal, selected from the group consisting of the received monitor signal and the further monitor signal, exceed a threshold value signal.

7. The communications module according to claim 6, comprising:
an OR device having a first input and a second input;
said safety device including a comparator device having a first input, a second input, and an output;
said safety device including a further comparator device having a first input, a second input, and an output;
the monitor signal being applied to said first input of said comparator device;
the further received monitor signal being applied to said first input of said further comparator device;
the threshold value signal being applied to said second input of said comparator device and to said second input of said further comparator device;
said output of said comparator device being connected to said first input of said OR device; and
said output of said further comparator device being connected to said second input of said OR device.
